(19) United States
(12) Patent Application Publication
(10) Pub. No.: US 2012/0048725 A1
(43) Pub. Date: Mar. 1, 2012

(54) NON-BONDED ROTARY SEMICONDUCTING TARGETS AND METHODS OF THEIR SPUTTERING

(75) Inventor: Russell Weldon Black, Longmont, CO (US)

(73) Assignee: PRIMESTAR SOLAR, INC., Arvada, CO (US)

(21) Appl. No.: 13/168,207

(22) Filed: Jun. 24, 2011

(51) Int. Cl. C23C 14/34

(52) U.S. Cl. 204/192.12; 204/298.02

(57) ABSTRACT

A rotary sputtering cathode, including a tubular member having a length in a longitudinal direction and defining an external surface, a first longitudinal bracket extending in the longitudinal direction along the length of the tubular member, and a second longitudinal bracket extending in the longitudinal direction along the length of the tubular member, is provided. Additional longitudinal brackets (e.g., a third, fourth, fifth, and so forth,) may also be included along the length of the tubular member. A target, which comprises a sputtering material, can be positioned such that its back surface is facing the external surface of the tubular member. The first longitudinal bracket and the second longitudinal bracket removably hold the first target therebetween such that the first back surface of the first target is facing the external surface of the tubular member. Methods are also provided for sputtering a non-bonded target.

### FIELD OF THE INVENTION

The subject matter disclosed herein relates generally to non-bonded, semiconducting targets and their use during sputtering of a semiconducting layer on a substrate.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials.

The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type layer (i.e., an electron accepting layer) and the CdS layer acts as a n-type layer (i.e., an electron donating layer). Free carrier pairs are created by light energy and then separated by the p-n heterojunction to produce an electrical current.

The CdS layer, along with other layers (e.g., a transparent conductive oxide layer of cadmium tin oxide) can be formed via a sputtering process (also know as physical vapor deposition) where the source material is supplied from a semiconducting target (e.g., cadmium sulfide, cadmium tin oxide, etc.). Typically, the cadmium sulfide semiconducting target is bonded to a backing plate that is water cooled and then placed into magnetrons (cathodes) that perform the sputtering action. The semiconducting target is typically bonded to the backing plate using indium solder or a conductive epoxy. The bond provides good thermal and electrical contact between the semiconducting target and the water cooled backing plate. Thus, the heat created by the plasma on the opposite side of the semiconducting target can be dissipated and carried away from the target by the water cooled backing plate.

As the semiconducting target is sputtered, the semiconducting material is eroded from the target. As the semiconducting target erodes, nodules form on the surface of the target that, over time, may change the deposition rate during sputtering and could affect the characteristics of the resulting thin film. Additionally, these nodules can cause arcs to form in the sputtering chamber. These variables created after sputtering over an extended period can lead to thin film variances of the deposited semiconducting layers in a large-scale, manufacturing environment, such as during the commercial manufacture of cadmium telluride based thin film photovoltaic devices.

Thus, a need exists for a more uniform sputtering process for the deposition of substantially uniform layers.

### BRIEF DESCRIPTION OF THE INVENTION

Aspects and advantages of the invention will be set forth in part in the following description, or may be obvious from the description, or may be learned through practice of the invention.

Rotary sputtering cathodes are generally provided. The cathode generally includes a tubular member having a length in a longitudinal direction and defining an external surface, a first longitudinal bracket extending in the longitudinal direction along the length of the tubular member, and a second longitudinal bracket extending in the longitudinal direction along the length of the tubular member. Additional longitudinal brackets (e.g., a third, fourth, fifth, and so forth,) may also be included along the length of the tubular member. A target, which comprises a sputtering material and defines a sputtering surface and a back surface that is opposite the sputtering surface, can be positioned such that its back surface is facing the external surface of the tubular member. The first longitudinal bracket and the second longitudinal bracket removably hold the first target therebetween such that the first back surface of the first target is facing the external surface of the tubular member.

Methods are also generally provided for sputtering a non-bonded target. First, a sputtering target can be removably inserted into a rotary sputtering cathode between a first bracket and a second bracket to expose a sputtering surface of the sputtering target. The sputtering cathode comprises a tubular member defining an external surface such that the sputtering target is positioned adjacent to the external surface and is non-bonded thereto. Then, the sputtering surface of the sputtering target can be contacted with a plasma such that atoms are ejected from the sputtering surface of the sputtering target.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a perspective view of an exemplary rotary sputtering cathode including a plurality of non-bonded semiconducting targets;

FIG. 2 shows a close-up perspective view of the exemplary rotary sputtering cathode of FIG. 1 without targets present;

FIG. 3 shows a cross-sectional view of the exemplary rotary sputtering cathode of FIG. 2;

FIG. 4 shows a perspective view of an exemplary target for use with the exemplary rotary sputtering cathode of FIG. 1;

FIG. 5 shows a cross-sectional view of the exemplary rotary sputtering cathode of FIG. 1 during sputtering;

FIG. 6 shows a cross-sectional view of an exemplary rotary sputtering cathode having removable bracket caps; and,

FIG. 7 shows a cross-sectional view of yet another exemplary sputtering cathode; and,

FIG. 8 shows a cross-sectional view of the exemplary rotary sputtering cathode of FIG. 7.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Rotary non-bonded semiconducting targets are generally provided, along with sputtering cathodes incorporating such rotary non-bonded targets. The rotary non-bonded target can be sputtered with a reduction, or substantial elimination, of nodules formed in the target's sputtering surface. Thus, the rotary non-bonded target can be more uniformly sputtered during the deposition process and can lead to the formation of more uniform thin film layers (e.g., cadmium sulfide thin film layers, cadmium tin oxide layers, etc.), both on a single substrate and throughout the manufacturing process (i.e., from substrate to substrate).

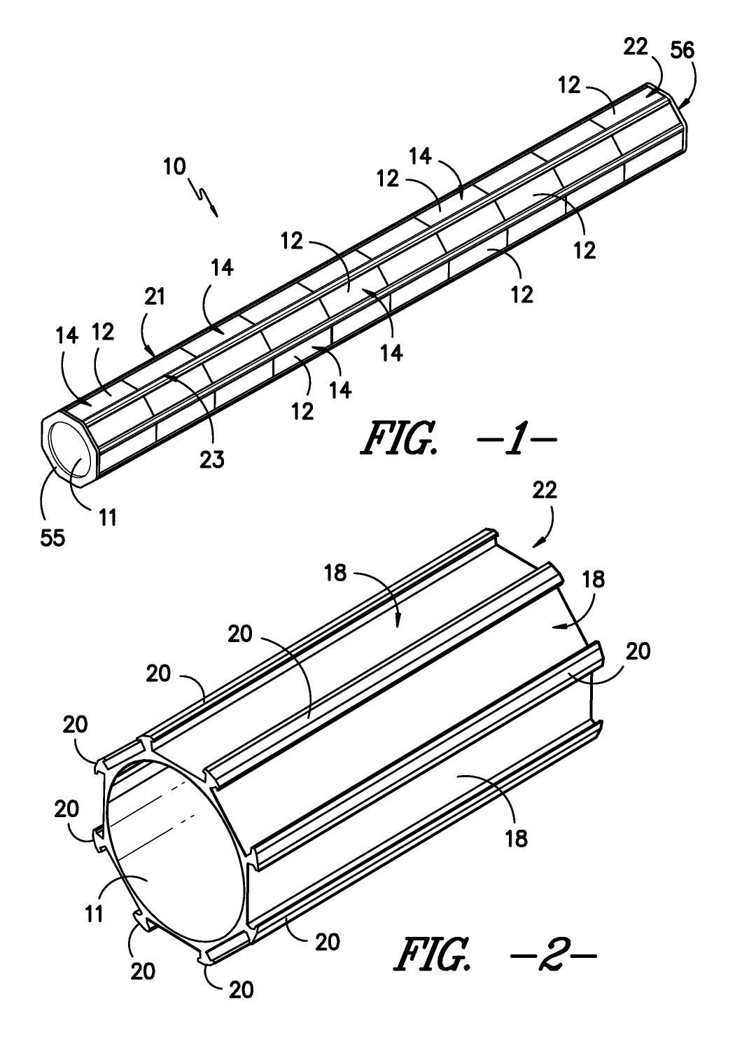

FIG. 1 shows an exemplary rotary sputtering cathode 10 including a tubular member 11 and a plurality of non-bonded targets 12. Though shown as having a generally cylindrical shape (e.g., a drum having a generally circular in its cross-section), the tubular member 11 can be formed into any suitable rotatable shape. For example, the tubular member 11 can be have a polygon-like cross-section, with the number of points generally matching the number of longitudinal brackets 20, as described below.

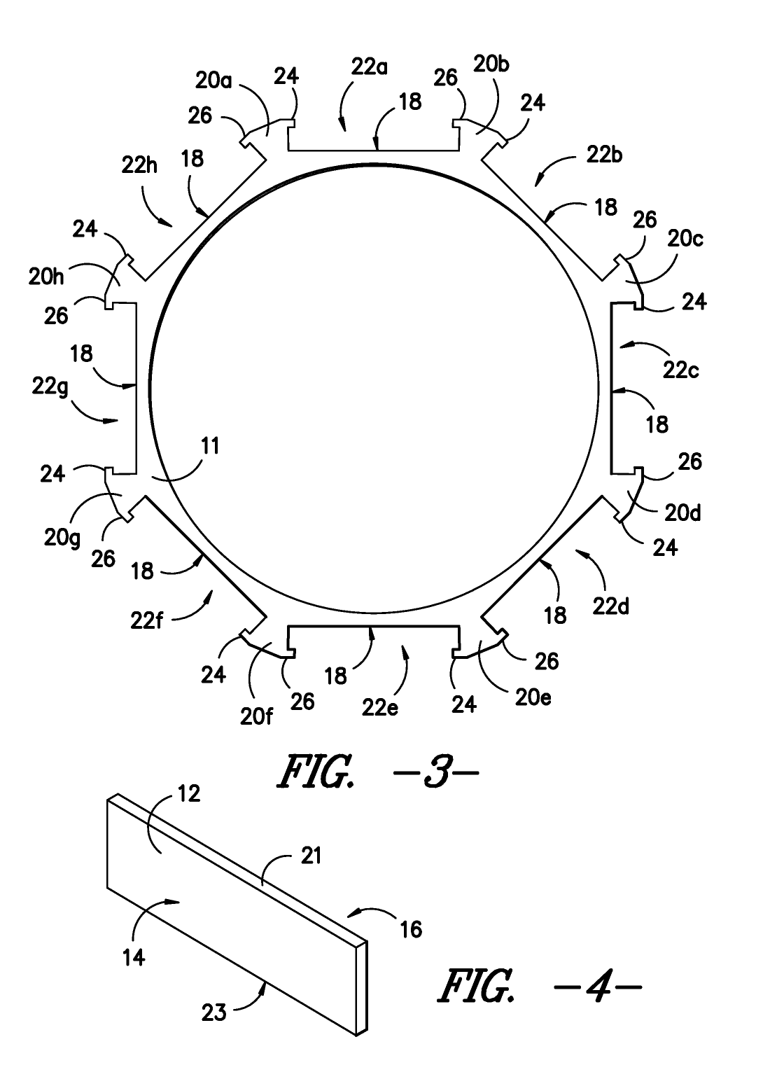

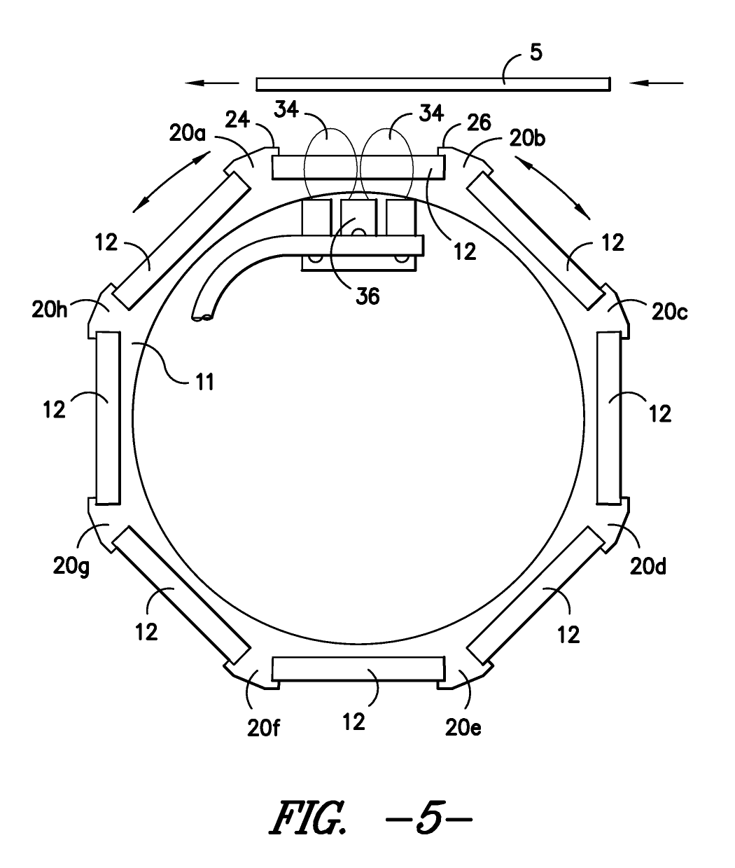

Each of the targets 12 define a sputtering surface 14 and a back surface 16 that is opposite the sputtering surface 14, as specifically shown in FIGS. 4, 6, and 8. The back surface 16 of each target 12, which is shown in FIGS. 2, 3, 6, and 8, remains non-bonded to the external surface 18 defined by the rotary sputtering cathode 10. As used herein, the term “non-bonded” refers to the target 12 being free from any attachment material between the back surface 16 of the target 12 and the external surface 18 of the rotary sputtering cathode 10 (i.e., no welding, solder, adhesive, or other attachment material is present between the back surface 16 of the target 12). As such, the target 12 can move freely with respect to the external surface 18, within the limits of the mounting structure provided (e.g., the brackets 20).

Since the targets 12 are not bonded to the external surface 18, thermal conduction therebetween may be inhibited, particularly in the relatively low vacuum pressures of the sputtering atmosphere (e.g., about 1 mTorr to about 50 mTorr) present during sputtering. Thus, the targets 12 may become hot due to the plasma in the sputtering chamber and/or a radiative heat source within the sputtering chamber. For any substantially constant sputtering process (i.e., with a substantially constant magnetron power, sputtering pressure, and/or sputtering temperature), the targets 12 can reach a relatively stable sputtering temperature when the thermal energy absorbed along the sputtering surface 14 is substantially equal to the thermal energy radiated from the back surface 16 of the target 12 to the external surface 18. For example, the sputtering temperature of the target 12 can be about 100° C. to about 1,000° C. depending on the particular sputtering parameters utilized.

As the plasma heats the target 12 during sputtering, the target 12 can maintain its sputtering temperature during sputtering due to the heat provided by the plasma without the need for additional heating elements to provide additional thermal energy to the targets 12. However, if the sputtering temperature decreases below the desired temperature, heating elements (not shown) can be included to provide additional thermal energy to the targets 12 to raise their sputtering temperature as desired. In one particular embodiment, the targets 12 can be pre-heated via heating elements 17 in or on the external surface 18, prior to sputtering (e.g., prior to formation of the plasma field). Thus, the targets 12 can be heated to the sputtering temperature, which can be substantially maintained during the entire sputtering process to provide uniform sputtering parameters. During sputtering of the targets 12, the sputtering temperature of the targets 12 can be maintained due to the plasma heating the targets 12 and/or the heating elements (when present).

In one particular embodiment, temperature sensors (not shown) can be included on or within the sputtering chamber and/or the sputtering cathode 10 to monitor the temperature of the sputtering surface 14 of the target 12. For example, the temperature sensor can be a non-contact temperature sensor, such as a pyrometer.

These relatively high sputtering temperatures of the target 12 limits the material of the target 12 to those materials capable of withstanding these sputtering temperatures and any potential temperature gradients formed through the thickness of the target 12 without substantial cracking or melting thereof. In one particular embodiment, the non-bonded targets can include cadmium sulfide to be used in methods for forming a cadmium sulfide layer via sputtering on a substrate, such as for use in cadmium telluride based thin film photovoltaic devices. When constructed of cadmium sulfide, the non-bonded cadmium sulfide target can also be sputtered at a lower power setting than typically required for an otherwise identical, but bonded target, while still achieving substantially the same deposition rate. Additionally, the non-bonded cadmium sulfide target can be easily interchanged upon depletion, resulting in significant time and cost savings. Alternatively, the material of the target 12 can include cadmium tin oxide and/or indium tin oxide, such as for forming a transparent conductive oxide layer on a substrate, such as for use in cadmium telluride based thin film photovoltaic devices. Of course, in the broadest sense, the material of the target 12 can be made of any sputtering material that a user wishes to sputter deposit onto a given surface. For example, the target 12 can be constructed of any sputtering material and may be particularly useful for refractory, ceramic, and/or semiconductor materials.

The target 12 can be held on or adjacent to the external surface 18 of the tubular member 11 via brackets or other non-bonding attachment mechanism(s). As shown in the Figs., each target 12 is generally positioned between a pair of longitudinal brackets 20 that extend in the longitudinal direction along the length of the tubular member 11. FIG. 1 shows a first bracket 20a and a second bracket 20b positioned along opposite edges 21, 23 (i.e., first edge 21 and second edge 23), respectively, of the targets 12 to form a first slot 22a. As such, the targets 12 can be removably held between the pair of longitudinal brackets 20 (i.e., generically described as a first and second bracket 20a, 20b) such that the back surface 16 of the target 12 can face the external surface 18 of the tubular member 11 while remaining unbonded thereto. Although shown with eight longitudinal brackets 20 (i.e., first bracket 20a, second bracket 20b, third bracket 20c, fourth bracket 20d, fifth bracket 20e, sixth bracket 20f, seventh bracket 20g, and eighth bracket 20h) forming eight slots (i.e., first slot 220a, second slot 22b, third slot 22c, fourth slot 22d, fifth slot 22e, sixth slot 22f, seventh slot 22g, and eighth slot 22h) therebetween, any suitable number of brackets 20 can be utilized as desired. As such, the number of longitudinal brackets 20 can match the number of slots 22 defined about the tubular member 11, and can be, in certain embodiments, from about 3 to about 12 (e.g., about 4 to about 10, or about 5 to about 8).

Each slot 22 can have a length in the longitudinal direction to match or exceed the length of the substrate 5 passing by during sputtering. As such, multiple targets 12 can be positioned in end to end fashion along the length of each slot 22.

Both the first bracket 20a and the second bracket 20b define overhang flanges 24, 26 extending from their respective leading edges 25, 27. Thus, the first bracket 20a and the second bracket 20b form a slot 22 for removably receiving targets 12 therebetween within the sputtering cathode 10. The slot 22 is bordered by the inner surface of each overhang flange 24, 26 extending from the respective brackets 20a, 20b; the side edges 28a, 28b of the first bracket 20a and the second bracket 20b, respectively; and, the external surface 18.

The first overhang flange 24 and the second overhang flange 26 extending from the first bracket 20a and the second bracket 20b, respectively, are each positioned to overlap a portion the sputtering surface 14 along the respective edges (i.e., first edge 21 and second edge 23) of the target 12. The overlap portion of the sputtering surface 14 that each overhang flange 24, 26 covers is sufficient to hold the target 12 within the sputtering cathode and adjacent to the external surface 18. However, the overlap portion of the sputtering surface 14 covered by the overhang flanges 24, 26 is preferably minimal, so as to avoid waste of the target material, since the overlap portion along the first edge 21 and second edge 23 of the target 12 will be inhibited from sputtering during the deposition process. For example, each overhang flange 24, 26 can cover about 0.5% to about 5% of the sputtering surface 14 extending from the first edge 21 and second edge 23 of the target 12, such as about 1% to about 4% of the sputtering surface 14.

The first bracket 20a and the second bracket 20b can hold and secure the target(s) 12 within the sputtering cathode 10 such that the back surface 16 is facing the external surface 18 during sputtering. As such, the back surface 16 of the target 12 can be in close proximity to or in direct contact with the external surface 18. Since the back surface 16 is non-bonded to the external surface 18, the target, however, is free to move with respect to the external surface 18 within the confines of the slot 22.

The longitudinal brackets 20 are shown to be substantially parallel to each other to form a slot 22 therebetween each adjacent longitudinal bracket 20, allowing the targets 12 to be inserted and removed from the rotary sputtering cathode 10 by sliding in the longitudinal direction. As shown in the embodiments depicted in the Figs., each of the longitudinal brackets 20 is positioned on the external surface 18 of the tubular member 11 in the longitudinal direction of a tangent plane with generally equal spacing therebetween. However, other configurations (e.g., differential spacing) may be utilized as desired.

Each longitudinal bracket 20 generally defines a pair of overhang flanges 24, 26, with a first overhange flange 24 extending in a first direction toward the adjacent bracket 20 on the first side and a second overhange flange 26 extending in a second direction toward the adjacent bracket 20 on the second (opposite) side. Each overhang flange 24, 26 is designed to removably hold a target 12 therebetween

In one particular embodiment, the targets 12 can be sized to fit securely within the slot 22, substantially allowing movement of the targets only along the length of the slot 22. For example, the spacing between the opposite side edges 28a, 28b of the first bracket 20a and the second bracket 20b, respectively, can be about 100.1% to about 105% of the width of the target 12 defined between the first edge 21 and second edge 23, such as about 100.5% to about 104%, and particularly about 101% to about 103%. Likewise, the spacing between the overhang flanges 24, 26 and the external surface 18 can be about 100.1% to about 110% of the thickness of the target 12 defined between the sputtering surface 14 and the back surface 16, such as about 100.5% to about 105%, and particularly about 101% to about 103%. Thus, 90% to about 99.8% of the sputtering surface 14 of the target 12 can remain exposed and available for sputtering, such as about 92% to about 99%, and particularly about 96% to about 98%.

The extra space in within the slot 22 can allow for the targets 12 to move relatively easily when at room temperature (e.g., about 20° C. to about 25° C.) but will still secure the targets 12 from falling out when the cathode is mounted vertically or upside-down. For example, the extra space allows for thermal expansion of the target at elevated sputtering temperatures (e.g., about 100° C. or more) while limiting, and potentially preventing, thermally-induced cracking of the target 12 as it is not mechanically restricted within its range of thermal expansion.

FIG. 1 shows one embodiment of the sputtering cathode 10 of FIG. 1 where the back surface 16 of the target 12 directly contacts the external surface 18. In this embodiment, no other material is present between the back surface 16 and the external surface 18. For instance, the spacing between the overhang flanges 24, 26 and the external surface 18 can be about 100.1% to about 102% of the thickness of the target 12 defined between the sputtering surface 14 and the back surface 16, such as about 100.2% to about 101.5%, and particularly about 100.5% to about 101%. Thus, little room is available for the target 12 to move between the overhang flanges 24, 26 and the external surface 18, particularly when the target 12 is heated, thereby causing expansion thereof.

In one embodiment, a layer of dielectric material (e.g., cadmium sulfide) can be included on the surface of the external surface 18 facing the target 12. This layer of dielectric material can prevent the external surface 18 from being sputtered upon depletion of the target 12. In one embodiment, the layer of dielectric material can include substantially the same material as the target 12 (e.g., having substantially identical construction). For instance, both the layer of dielectric material and the target 12 can include cadmium sulfide.

Alternatively, a gap can exist between the back surface 16 of the target 12 and the external surface 18 to allow a particular amount of float between the external surface 18 and the overhang flanges 24, 26 of the first and second bracket 20a, 20b. For instance, the spacing between the overhang flanges 24, 26 and the external surface 18 can be about 102% to about 105% of the thickness of the target 12 as defined between the sputtering surface 14 and the back surface 16. This configuration can allow for the targets 12 to easily slide within the slot 22 for relatively easy interchangeability.

In yet another alternative embodiment of the sputtering cathode 10, a spacer or biasing member (not shown) can be positioned between the back surface 16 of the target 12 and the external surface 18 such that a gap exists between the back surface 16 and the external surface 18. For example, a spacer can be positioned within each slot 28 between the back surface 16 of the target 12 and the external surface 18. The size of the spacer can be controlled as desired, to control the distance between the back surface 16 and the external surface 18. The biasing member can be located between the external surface 18 and the target 12 to provide a force pushing the target 12 against the brackets 20.

The gap, when present between the back surface 16 of the target 12 and the external surface 18, can be adjusted to control the equilibrium sputtering temperature of the target 12 during the sputtering process, which can lead to better control of the deposition rate and/or deposition uniformity. The gap can be, in certain embodiments, about 100 μm to about 1 cm, such as about 200 μm to about 0.5 cm.

The spacing between the brackets 20 and the external surface 18 can be adjusted as needed according to the thickness of the targets 12 and the desired amount of float to be present in the slot 22. In the embodiments shown in FIG. 6, for example, a fastener 30 (e.g., a bolt, screw, pin, etc.) is included to adjust the distance of the overhang flanges 24, 26 extending from the external surface 18 of the tubular member 11 at each bracket 20.

The brackets 20 (and/or tubular member 11) can be, in one embodiment, constructed of a non-magnetic material so as to avoid any influence on the magnetic field formed during sputtering. For example, the brackets 20 can be formed non-magnetic metal material (e.g., stainless steel, such as 304 type stainless steel or 316 type stainless steel). In one particular embodiment, such as when the targets 12 include cadmium sulfide, the exposed surfaces of the brackets 20 can be coated with cadmium, in the event that the brackets 20 are sputtered during the deposition process. A layer of cadmium on the surface of the first and second brackets 20 can prevent sputtering of the brackets 20 themselves, thereby inhibiting contamination of the sputtering chamber (and the resulting deposited film). For example, FIG. 6 shows that the exposed surface of the brackets 20 (including the overhang flanges 24, 26) are formed from a bracket cap 32 secured via fastener 30 onto the tubular member 11 to form the bracket 20. Such a bracket cap 32 can be formed from a material included in the target 12 (e.g., cadmium). As such, the use of the term “bracket” includes both a single-piece bracket (e.g., part of or welded or otherwise connected to the external surface 18 of the tubular member 11) and a multiple-piece bracket (e.g., formed from multiple components such as a bracket cap 32, a fastener 30, etc.)

The external surface 18 can be connected to a cooling system (not shown) to help collect and remove thermal energy from the external surface 18 of the tubular member 11.

In one particular embodiment, the targets 12 are rectangular so as to have substantially parallel sides. This rectangular configuration can allow the targets 12 to readily form a substantially uniform sputtering surface across multiple targets within the sputtering cathode 10. Thus, gaps between adjacent targets 12 can be avoided, preventing sputtering of the underlying external surface 18 during the sputtering process. Additionally, the rectangular configuration can allow the targets 12 to be readily changed and replaced utilizing the slot 22.

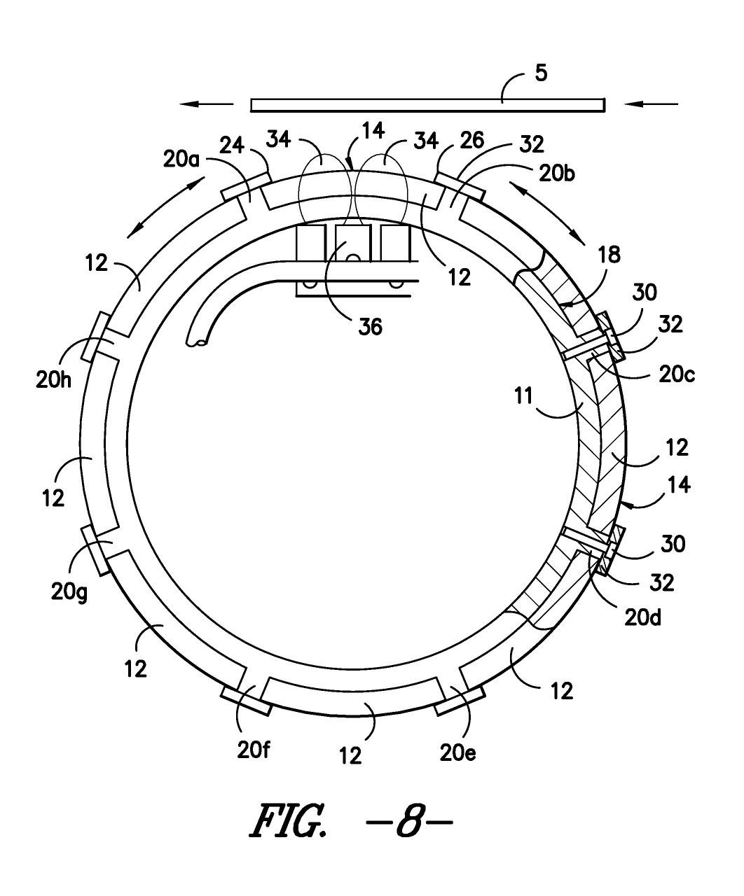

In the embodiments shown in FIGS. 1-6, the targets 12 have a substantially planar sputtering surface 14 and back surface 16 prior to sputtering, along with a substantially planar external surface 18 of the tubular member 11 between the brackets 20. However, FIGS. 7 and 8 show an alternative embodiment where the external surface 18 of the tubular member 11 is curved (e.g., arcuate) between the brackets 20. As such, the targets 12 can have a curved back surface 16, which can be substantially parallel to the curve defined by the external surface 18 of the tubular member 11. That is, the arc of the curved back surface 16 could match that of the adjacent curve of the external surface 18, in the instance where the tubular member 11 is cylindrical. Additionally, the sputtering surface 14, prior to sputtering, can also be curved (e.g., arcuate) to be substantially parallel to the curve defined by the external surface 18 of the tubular member 11. This curved configuration can allow for the distance between the closest point of the sputtering surface 14 and the substrate 5 to remain substantially uniform as the tubular member 11 is oscillated during sputtering, which can lead to improved uniformity during sputtering. In one particular embodiment, for example, the curved surface (of the sputtering surface 14, back surface 16, and/or the external surface 18) can be generally follow the circumference of the tubular member 11, when circular in a cross-section, in the segment defined between adjacent brackets 20 (e.g., the first bracket 20a and the second bracket 20b).

The tubular member 11 is shown having a hollow cylinder-like configuration. However, it is to be understood that internal elements may be included within the construction of the tubular member 11, such as support structures (e.g., spokes), magnets, cooling devices, etc.

The sputtering cathode 10 can be utilized with any sputtering process. Sputtering deposition generally involves ejecting material from the target, which is the material source, by contacting the target with a plasma. The ejected material can then be deposited onto the substrate to form the film. DC sputtering generally involves applying a voltage to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. The pressure of the reactive atmosphere can be between about 1 mTorr and about 20 mTorr for magnetron sputtering. When metal atoms are released from the target upon application of the voltage, the metal atoms can react with the plasma and deposit onto the surface of the substrate. For example, when the atmosphere contains oxygen, the metal atoms released from the metal target can form a metallic oxide layer on the substrate. Conversely, RF sputtering generally involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere), and can have a relatively low sputtering pressure (e.g., about 1 mTorr and about 20 mTorr).

In one particular embodiment, the targets 12 include cadmium sulfide, such that the sputtering cathode 10 can be utilized to deposit a cadmium sulfide layer on a substrate. As stated, the non-bonded semiconducting target can be inserted into the sputtering cathode, optionally pre-heated to a sputtering temperature via heating elements, and thereafter, contacted with a plasma to eject atoms from the sputtering surface of the target. In certain embodiments, the sputtering temperature can be monitored throughout the heating and sputtering of the target (e.g., about 100° C. to about 1000° C.) via a temperature sensor positioned within the sputtering cathode, and adjusted as desired by increasing or decreasing the output of the heating elements.

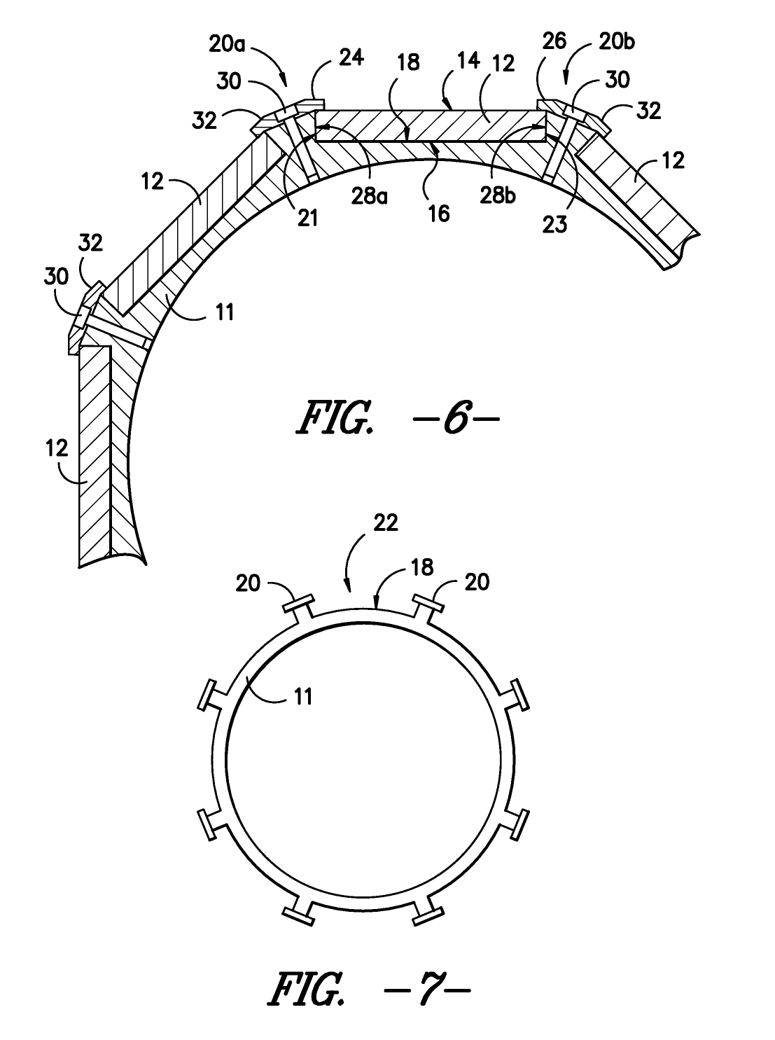

During the sputtering processes, the tubular member 11 can be rotationally oscillated between the pair of brackets 20 holding the target(s) 12 being sputtered. For example, a circumferential point in the first slot 22a on the arc length defined between the first bract 20a and the second bracket 20b can travel back-and-forth circumferentially in the first position without allowing sputtering of any targets 12 in any other slot 22b-22h. As such, the targets 12 can be sputtered in a substantially uniform manner, minimizing the “race-track” depletion normally seen with sputtering a fixed target. An oscillating motor (not shown) can be operably connected to the tubular member 10 to create such rotational oscillation. The distance traveled during rotational oscillation is generally an amount sufficient to keep the target(s) 12 in a slot 22 being sputtered within the electromagnetic field 34 created by the magnet 36 during sputtering. Referring to FIG. 5, for example, the cathode 10 can rotationally oscillate between the first bracket 20a and second bracket 20b to keep the targets 12 in the first slot 22a within the electromagnetic field 34 while the substrate 5 passes by the electromagnetic field 34 for deposition thereon. Rotational oscillation can occur at a rate that is generally faster than the speed of the substrate 5 passing by through the electromagnetic field 34, in order to keep deposition at a substantially constant deposition rate across the surface of the substrate 5.

As stated, sputtering of the first targets 12 in the first slot 22a can be achieved by facing (and, optionally, oscillating) the first slot 22a toward the substrate 5, which defines a first position of the cathode 10. Upon depletion of the first targets 12 in the first slot 22a via sputtering, the entire tubular member 11 can be rotated from the first position to a second position where the second targets 12 in the second slot 22b face the substrate 5 and can be sputtered. And, upon depletion of the targets 12 in the second slot 22b via sputtering, the entire tubular member 11 can be rotated from the second position to the third position where the third targets 12 in the third slot 22c face the substrate and can be sputtered. This rotation can be repeated for each slot 22, where the cathode 10 defines a sputtering position for each slot 22. Thus, the rotary sputtering cathode 10 can be sputtered in a manufacturing setting through a series of slots 22, without having to stop the manufacturing process to replenish depleted targets 12. This advantage can allow the manufacturing process to have fewer interruptions, saving not only time but also the amount of energy consumed since the vacuum (i.e., the sputtering pressure) does not have to be redrawn each time the targets 12 of a slot 22 are depleted.

Depleted targets 12, after being sputtered, can be readily changed by removing the first end plate 55 and/or the second end plate 56, allowing for the targets 12 to removed out of the slot 22 by sliding the targets toward the open end(s) following the length of the slot 22. Then, replacement targets 12 can be inserted into the slot 22 through the open end(s) to provide fresh source material for the sputtering process. The first end plate 55 and the second end plate 56 can be removably attached to the sputtering cathode 10 by any appropriate mechanism (e.g., bolted).

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A rotary sputtering cathode, comprising:
a tubular member having a length in a longitudinal direction and defining an external surface;
a first longitudinal bracket extending in the longitudinal direction along the length of the tubular member;
a second longitudinal bracket extending in the longitudinal direction along the length of the tubular member; and,
a first target comprising a first sputtering material and defining a first sputtering surface and a first back surface, wherein the first back surface is opposite the first sputtering surface and positioned facing the external surface of the tubular member, and wherein the first longitudinal bracket and the second longitudinal bracket removably hold the first target therebetween such that the first back surface of the first target is facing the external surface of the tubular member and nonbonded thereto.

2. The rotary sputtering cathode as in claim 1, further comprising:
a third longitudinal bracket extending in the longitudinal direction along the length of the tubular member; and,
a second target comprising a second sputtering material defining a second sputtering surface and a second back surface, wherein the second back surface is opposite the second sputtering surface and positioned facing the external surface of the tubular member, and wherein the second longitudinal bracket and the third longitudinal bracket removably hold the second target therebetween such that the second back surface of the second target is facing the external surface of the tubular member and nonbonded thereto.

3. The rotary sputtering cathode as in claim 2, further comprising:
a fourth longitudinal bracket extending in the longitudinal direction along the length of the tubular member; and,
a third target comprises a third semiconducting material defining a third sputtering surface and a third back surface, wherein the third back surface is opposite the third sputtering surface and positioned facing the external surface of the tubular member, and wherein the third longitudinal bracket and the fourth longitudinal bracket removably hold the third target therebetween such that the third back surface of the third target is facing the external surface of the tubular member.

4. The rotary sputtering cathode as in claim 1, wherein the back surface defines a substantially planar surface.

5. The rotary sputtering cathode as in claim 1, wherein the back surface defines a substantially curved surface.

6. The rotary sputtering cathode as in claim 1, wherein the first sputtering surface defines a substantially curved surface.

7. The rotary sputtering cathode as in claim 1, wherein the first bracket and the second bracket both define a pair of overhang flanges.

8. The rotary sputtering cathode as in claim 1, wherein the first bracket defines an exposed surface, wherein the exposed surface comprises a sputtering material.

9. The rotary sputtering cathode as in claim 1, further comprising:
a first bracket cap attached to the first bracket such that the first bracket cap is exposed during sputtering; and,
a second bracket cap attached to the second bracket such that the second bracket cap is exposed during sputtering.

10. The rotary sputtering cathode as in claim 9, wherein the first bracket cap and the second bracket cap comprise the first sputtering material.

11. The rotary sputtering cathode as in claim 9, wherein the first bracket plate is removably secured to the first bracket, and wherein the second bracket plate is removably secured to the second bracket.

12. A method of sputtering a non-bonded target, the method comprising:
removably inserting a sputtering target into a slot of a rotary sputtering cathode to expose a sputtering surface of the sputtering target, wherein the sputtering cathode comprises a tubular member defining an external surface such that the sputtering target is positioned adjacent to the external surface and non-bonded thereto; and,
contacting the sputtering surface of the sputtering target with a plasma such that atoms are ejected from the sputtering surface of the sputtering target.

13. The method of claim 12, further comprising:
heating the sputtering surface of the sputtering target to a sputtering temperature.

14. The method of claim 13, wherein the sputtering temperature is about 100° C. to about 1,000° C.

15. The method of claim 12, wherein the sputtering surface of the sputtering target increases in temperature upon initial contact with the plasma.

16. The method of claim 15, further comprising:
allowing the sputtering target to establish an equilibrium sputtering temperature during sputtering.

17. The method of claim 16, wherein the equilibrium sputtering temperature is about 100° C. to about 1,000° C.

18. The method of claim 12, further comprising:
oscillating the rotary sputtering cathode.

19. The method of claim 12, further comprising:
rotating the rotary sputtering cathode from a first position into a second position such that a second sputtering target is in position to contact the plasma.

20. A rotary sputtering cathode, comprising:
a tubular member defining an external surface; and,
a plurality of longitudinal brackets positioned about the external surface of the tubular member, wherein adjacent longitudinal brackets define a slot therebetween and are configured to removably hold non-bonded targets therebetween for sputtering thereof.
